(19) United States
(12) Patent Application Publication
(10) Pub. No.: US 2014/0057086 A1
(43) Pub. Date: Feb. 27, 2014

(54) Halogen Free Thermoset Resin System for Low Dielectric Loss at High Frequency Applications

(71) Applicants: Roger Tietze, The Woodlands, TX (US); Yen-Loan Nguyen, Spring, TX (US)

(72) Inventors: Roger Tietze, The Woodlands, TX (US); Yen-Loan Nguyen, Spring, TX (US)

(73) Assignee: Huntsman Advanced Materials Americas LLC, The Woodlands, TX (US)

(21) Appl. No.: 14/110,522

(22) PCT Filed: May 9, 2012
(86) PCT No.: PCT/US12/37011

§ 371 Date: Oct. 8, 2013

Related U.S. Application Data
(60) Provisional application No. 61/486,840, filed on May 17, 2011.

(51) Int. Cl. C08L 71/08; H05K 1/03

(52) U.S. Cl. CPC C08L 71/08; H05K 1/0366
USPC 428/196; 525/152; 524/130; 524/508; 427/58; 442/59; 442/180; 428/458; 442/172

(57) ABSTRACT

The present disclosure provides a thermosetting resin composition including a polymaleimide prepolymer and a poly(arylene ether) prepolymer characterized in that a resultant cured product formed by curing the thermosetting resin composition possesses high heat resistance and low dielectric loss at high frequency. The thermosetting resin composition is especially suited for use in high speed printed circuit boards, semiconductor devices and radome composites for aerospace applications.

### CROSS-REFERENCE TO RELATED APPLICATIONS

Not Applicable.

### STATEMENT REGARDING FEDERALLY SPONSORED RESEARCH OR DEVELOPMENT

Not Applicable.

### FIELD OF INVENTION

This present disclosure relates to polymaleimide-based thermosetting resin compositions and to their uses in various applications, such as, in the production of a prepreg, a laminated board for printed wiring board, a molding material and an adhesive.

### BACKGROUND OF THE INVENTION

Articles prepared from resin compositions having improved resistance to elevated temperatures as well as low dielectric loss are desirable for many applications. In particular, such articles are desirable for use in prepregs and laminates for printed circuit board (PCB) and semiconductor applications as industries head toward higher circuit densities, increased board thickness, lead free solders, higher temperature and higher frequency use environments.

Laminates, and particularly structural and electrical copper clad laminates, are generally manufactured by pressing, under elevated temperatures and pressures, various layers of partially cured prepregs and optionally copper sheeting. Prepregs are generally manufactured by impregnating a curable thermosettable epoxy resin composition into a porous substrate, such as a glass fiber mat, followed by processing at elevated temperatures to promote a partial cure of the epoxy resin in the mat to a “B-stage.” Complete cure of the epoxy resin impregnated in the glass fiber mat typically occurs during the lamination step when the prepreg layers are pressed under high pressure and elevated temperatures for a certain period of time.

While epoxy resin compositions are known to impart enhanced thermal properties for the manufacture of prepregs and laminates, such epoxy resin compositions are typically more difficult to process, more expensive to formulate, and may suffer from inferior performance capabilities for complex printed circuit board circuitry and for higher fabrication and usage temperatures.

In light of the above, there is a need in the art for resin compositions which may be used in preparing articles having improved thermal properties and low dielectric loss at high frequency and for processes to produce such articles.

### SUMMARY OF THE INVENTION

The present disclosure provides a thermosetting resin composition including:

(a) a polymaleimide prepolymer resulting from the advancement reaction of a polyimide and an alkenylphenol, alkenylphenol ether or mixture thereof in the presence of an amine catalyst;

(b) a poly(arylene ether) prepolymer resulting from the advancement reaction of a poly(arylene ether) and an allyl monomer optionally in the presence of a catalyst; characterized in that a resultant cured product formed by curing the thermosetting resin composition contains at least two of the following well-balanced properties: (1) a glass transition temperature (Tg) of greater than about 170° C.; (2) a UL94 flame retardancy ranking of at least V1; (3) a dielectric loss tangent of less than 0.005 at 16 GHz; and, (4) a dielectric constant of less than 3.00 at 16 GHz.

Another aspect of the present disclosure is directed to the use of the above thermosetting resin composition to obtain a prepreg or a metal-coated foil; and, to a laminate obtained by laminating the prepreg and/or the metal-coated foil.

### DETAILED DESCRIPTION OF THE INVENTION

In accordance with certain embodiments, the thermosetting resin compositions disclosed herein are substantially halogen-free or halogen-free. As used herein the term “substantially halogen-free” refers to compositions that do not include any covalently bonded halogen groups in the final composition, but may include minimal amounts of residual halogens that are present in any remaining halogenated solvent or catalyst or residual amounts of halogen that leaches from any containers or glassware used to synthesize and/or store the compositions. In certain examples, substantially halogen-free refers to less than about 0.12% by weight total halogen content in the final composition, more particularly less than about 0.09% by weight total halogen content in the final composition. Though residual amounts of halogen may be present in the final compositions, the residual amount does not impart, or retract from, the physical properties, e.g., flame retardancy, peel strength, dielectric properties, etc., of the final composition. In addition, any residual amounts of halogen that are present do not generate appreciable amounts of dioxin, or other toxic substances, during burning to be considered a health hazard to mammals, such as humans.

It will be recognized by persons of ordinary skill in the art, given the benefit of this disclosure, that the thermosetting resin compositions, and articles made using the thermosetting resin compositions, provide significant advantages not achieved with state of the art compositions. The thermosetting resin compositions may be used in the assembly of various single and multi-layered articles including, but not limited to, laminates, printed circuit boards, molded articles, automotive and aircraft plastics, silicon chip carriers, structural composites, radome composites for aerospace applications, resin coated foils, unreinforced substrates for high density circuit interconnect applications and other suitable applications where it may be desirable to use single or multi-layered articles having flame retardant and/or excellent electrical properties especially at high frequency.

According to one aspect, the present disclosure is directed to a thermosetting resin composition including: (a) a polymaleimide prepolymer resulting from the advancement reaction of a polyimide and an alkenylphenol, alkenylphenol ether or mixture thereof in the presence of an amine catalyst; (b) a poly(arylene ether) prepolymer resulting from the advancement reaction of a poly(arylene ether) and an allyl monomer optionally in the presence of a catalyst; characterized in that a resultant cured product formed by curing the thermosetting resin composition contains at least two of the following well-balanced properties: (1) a glass transition temperature (Tg) of greater than about 170° C.; (2) a UL94 flame retardancy ranking of at least V1; (3) a dielectric loss tangent of less than 0.005 at 16 GHz; and (4) a dielectric constant of less than 3.00 at 16 GHz. As used herein, an “advancement reaction” refers to a reaction in which the molecular weight of a particular compound is increased. In comparison, a “cured product” refers to the curing of a thermoset resin whereby substantial networking or cross-linking occurs.

Polymaleimide Prepolymer

According to one embodiment, the thermosetting resin composition of the present disclosure includes from about 3-20 parts by weight, preferably from about 5-18 parts by weight, and more preferably from about 7-15 parts by weight, per 100 parts by weight of the thermosetting resin composition, of a polymaleimide prepolymer resulting from the advancement reaction of polyimide and an alkenylphenol, alkenylphenol ether or mixture thereof in the presence of an amine catalyst.

Applicable polyimide's contain at least two radicals of the formula

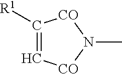

where R¹ is hydrogen or methyl. In one embodiment, the polyimide is a bismaleimide of the formula

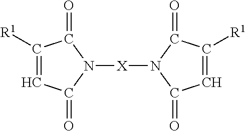

where R¹ is hydrogen or methyl and X is —CᵢH₂ᵢ— with i=2 to 20, —CH₂CH₂SCH₂CH₂—, phenylene, naphthalene, xylene, cyclopentylene, 1,5,5-trimethyl-1,3-cyclohexylene, 1,4-cyclohexylene, 1,4-bis-(methylene)-cyclohexylene, or groups of the formula

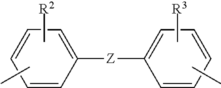

where R² and R³ independently are methyl, ethyl, or hydrogen and Z is a direct bond, methylene, 2,2-propylidene, —CO—, —O—, —S—, —SO— or —SO₂—. Preferably, R¹ is methyl, X is hexamethylene, trimethylhexamethylene, 1,5,5-trimethyl-1,3-cyclohexylene or a group of the indicated formula (a) in which Z is methylene, 2,2-propylidene or —O— and R² and R³ are hydrogen.

Applicable alkenylphenols and alkenylphenol ethers may include allylphenols, methallylphenols or ethers thereof. Preferably, the alkenylphenol and alkenylphenol ether is a compound of the formulae (1)-(4):

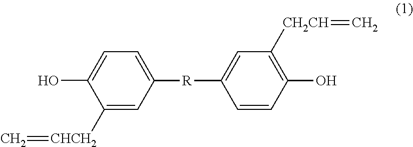

where R is a direct bond, methylene, ispopropylidene, —O—, —S—, —SO— or —SO₂—;

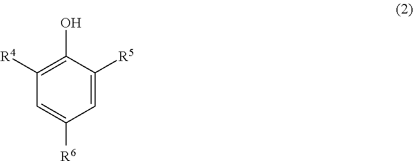

where R⁴, R⁵ and R⁶ are each independently hydrogen or a C₂-C₁₀ alkenyl, preferably an allyl or propenyl, with the proviso that at least one of R⁴, R⁵ or R⁶ is a C₂-C₁₀ alkenyl;

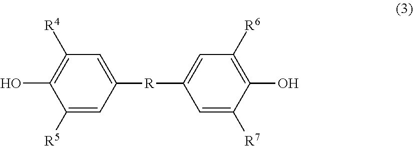

where R⁴, R⁵, R⁶ and R⁷ are each independently hydrogen or a C₂-C₁₀ alkenyl, preferably an allyl or alkenyl, with the proviso that at least one of R⁴, R⁵, R⁶ or R⁷ is a C₂-C₁₀ alkenyl and R is defined as in formula (1) and (4)

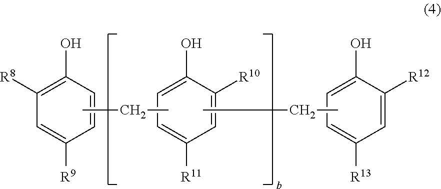

where R⁸, R⁹, R¹⁰, R¹¹, R¹² and R¹³ are each independently hydrogen, C₁-C₄ alkyl, and C₂-C₁₀ alkenyl, preferably allyl or propenyl, with the proviso that at least one of R⁸, R⁹, R¹⁰, R¹¹, R¹² and R¹³ is a C₂-C₁₀ alkenyl and b is an integer from 0 to 10. It is also possible to use mixtures of compounds of the formulae (1)-(4).

Examples of alkenylphenol and alkenylphenol ether compounds include: O,O′-diallyl-bisphenol A, 4,4′-dihydroxy-3,3′-diallyldiphenyl, bis(4-hydroxy-3-allylphenyl)methane, 2,2-bis(4-hydroxy-3,5-diallylphenyl)propane, O,O′-dimethallyl-bisphenol A, 4,4′-dihydroxy-3,3′-dimethallyldiphenyl, bis(4-hydroxy-3-methallylphenyl)methane, 2,2-bis(4-hydroxy-3,5-dimethallylphenyl)-propane, 4-methallyl-2-methoxyphenol, 2,2-bis(4-methoxy-3-allylphenyl)propane, 2,2-bis(4-methoxy-3-methallylphenyl)propane, 4,4′-dimethoxy-3,3′-diallyldiphenyl, 4,4′-dimethoxy-3,3′-dimethallyldiphenyl, bis(4-methoxy-3-allylphenyl)methane, bis(4-methoxy-3-methallylphenyl)methane, 2,2-bis(4-methoxy-3,5-diallylphenyl)propane, 2,2-bis(4-methoxy-3,5-dimethallylphenyl)propane, 4-allylveratrole and 4-methallyl-veratrole.

The alkenylphenol, alkenylphenol ether or mixture thereof may be employed in a range of between about 0.05 moles-2.0 moles per mole of polyimide. In another embodiment, the alkenylphenol, alkenylphenol ether or mixture thereof may be employed in a range of between about 0.1 moles-1.0 mole per mole of polyimide.

Applicable amine catalysts include tertiary, secondary and primary amines or amines which contain several amino groups of different types and quaternary ammonium compounds. The amines may be either monoamines or polyamines and may include: diethylamine, tripropylamine, tributylamine, triethylamine, triamylamine, benzylamine, tetramethyl-diaminodiphenylmethane, N,N-diisobutylaminoacetonitrile, N,N-dibutylaminoacetonitrile, heterocyclic bases, such as quinoline, N-methylpyrrolidine, imidazole, benzimidazole and their homologues, and also mercaptobenzothiazole. Examples of suitable quaternary ammonium compounds which may be mentioned are benzyltrimethylammonium hydroxide and benzyltrimethylammonium methoxide. Tripropylamine is preferred.

The basic catalyst may be employed in a range of between about 0.1%-10% by weight of basic catalyst per total weight of the advancement reactants. In another embodiment, the basic catalyst present may be employed in a range of between about 0.2%-5% by weight of basic catalyst per total weight of the advancement reactants.

The method of preparing the polymaleimide prepolymer includes blending the polyimide and the alkenylphenol, alkenylphenol ether or mixture thereof and heating the blend to a temperature of about 25° C.-150° C. until a clear melt is obtained. The amine catalyst may then be added and the reaction continued for an appropriate amount of time at a temperature of about 100° C.-140° C. whereupon all of the amine catalyst is removed under vacuum. The degree of advancement may be monitored by measuring resin melt viscosity using a 0-100 poise scale at 125° C. and may range from 20-85 poise for the advanced polymaleimide prepolymer. Gel time may also be used as an additional parameter and reflects the time to total gel formation as determined at a temperature of about 170° C.-175° C. and may range from 300-2000 seconds.

Poly(Arylene Ether) Prepolymer

The thermosetting resin composition of the present disclosure also includes from about 80-97 parts by weight, preferably from about 82-95 parts by weight, per 100 parts by weight of the thermosetting resin composition, of a poly(arylene ether) prepolymer resulting from the advancement reaction of a poly(arylene ether) and an allyl monomer.

In one embodiment, the poly(arylene ether) includes one or more compounds containing a plurality of structural units having the formula

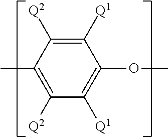

where for each structural unit, each occurrence of Q¹ is independently primary or secondary C₁-C₁₂ hydrocarbyl, C₁-C₁₂ hydrocarbylthio or C₁-C₁₂ hydrocarbyloxy; and each occurrence of Q² is independently primary or secondary C₁-C₁₂ hydrocarbyl, C₁-C₁₂ hydrocarbyloxy or C₁-C₁₂ hydrocarbyloxy. The term “hydrocarbyl”, whether used by itself, or as a prefix, suffix, or fragment of another term, refers to a residue that contains only carbon and hydrogen. The residue can be aliphatic or aromatic, straight-chain, cyclic, bicyclic, branched, saturated, or unsaturated. It can also contain combinations of aliphatic, aromatic, straight chain, cyclic, bicyclic, branched, saturated, and unsaturated hydrocarbon moieties. However, when the hydrocarbyl residue is described as “substituted”, it can contain heteroatoms over and above the carbon and hydrogen members of the substituent residue. Thus, when specifically described as substituted, the hydrocarbyl residue can also contain nitro groups, cyano groups, carbonyl groups, carboxylic acid groups, ester groups, amino groups, amide groups, sulfonyl groups, sulfoxyl groups, sulfonamide groups, sulfamoyl groups, hydroxyl groups, alkoxyl groups, or the like, and it can contain heteroatoms within the backbone of the hydrocarbyl residue.

In some embodiments, the poly(arylene ether) contains 2,6-dimethyl-1,4-phenylene ether units, 2,3,6-trimethyl-1,4-phenylene ether units, or a combination thereof. In other embodiments, the poly(arylene ether) is a poly(2,6-dimethyl-1,4-phenylene ether) while in other embodiments, the poly(arylene ether) is a copolymer of 2,6-dimethyl phenol and 2,3,6-trimethyl phenol.

The poly(arylene ether) may also contain molecules having aminoalkyl-containing end groups, typically located at a position ortho to the hydroxy group. Also, frequently present are tetramethyl diphenoquinone (TMDQ) end groups, typically obtained from 2,6-dimethylphenol-containing reaction mixtures in which tetramethyl diphenoquinone by-product is present.

In some embodiments, the poly(arylene ether) may be in the form of a homopolymer, a copolymer, a graft copolymer, an ionomer, or a block copolymer as well as combinations thereof.

The poly(arylene ether) can be prepared by the oxidative coupling of monohydroxyaromatic compound(s) such as 2,6-dimethylphenol and/or 2,3,6-trimethylphenol. Catalyst systems are generally employed for such coupling; they can contain heavy metal compound(s) such as a copper, manganese or cobalt compound, usually in combination with various other materials such as a secondary amine, tertiary amine, halide or combination of two or more of the foregoing.

In other embodiments, the poly(arylene ether) can have a number average molecular weight of 3,000-40,000 grams per mole (g/mol) and a weight average molecular weight of 5,000-80,000 g/mol, as determined by gel permeation chromatography using monodisperse polystyrene standards, a styrene divinyl benzene gel at 40° C. and samples having a concentration of 1 milligram per milliliter of chloroform. The poly(arylene ether) or combination of poly(arylene ether)s may have an initial intrinsic viscosity of 0.1-0.60 deciliters per gram (dl/g), as measured in chloroform at 25° C. Initial intrinsic viscosity is defined as the intrinsic viscosity of the poly(arylene ether) prior to melt mixing with the other components of the composition and final intrinsic viscosity is defined as the intrinsic viscosity of the poly(arylene ether) after melt mixing with the other components of the composition. As understood by one of ordinary skill in the art the viscosity of the poly(arylene ether) may be up to 30% higher after melt mixing. The percentage of increase can be calculated by (final intrinsic viscosity-initial intrinsic viscosity)/initial intrinsic viscosity. Determining an exact ratio, when two initial intrinsic viscosities are used, will depend somewhat on the exact intrinsic viscosities of the poly(arylene ether) used and the ultimate physical properties that are desired.

According to another embodiment, the poly(arylene ether) is a functionalized poly(arylene ether). The functionalized poly(arylene ether) may be a capped poly(arylene ether), a di-capped poly(arylene ether), a ring-functionalized poly(arylene ether) or a poly(arylene ether) resin containing at least one terminal functional group selected from carboxylic acid, glycidyl ether, vinyl ether and anhydride.

In one embodiment, the functionalized poly(arylene ether) contains a capped poly(arylene ether) having the formula

A(J-K)_{y}

where A is the residuum of a monohydric, dihydric or polyhydric phenol, y is an integer of 1 to 100, preferably of 1-6, J is a compound of the formula

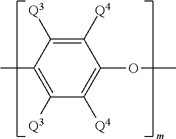

where for each structural unit, each occurrence of Q³ is independently primary or secondary C₁-C₁₂ alkyl, C₂-C₁₂ alkenyl, C₂-C₁₂ alknyl, C₁-C₁₂ aminoalkyl, C₁-C₁₂ hydroxyalkyl, phenyl, or C₁-C₁₂ hydrocarbyloxy; and each occurrence of Q⁴ is independently primary or secondary C₁-C₁₂ alkyl, C₂-C₁₂ alkenyl, C₂-C₁₂ alknyl, C₁-C₁₂ aminoalkyl, C₁-C₁₂ hydroxyalkyl, phenyl, or C₁-C₁₂ hydrocarbyloxy; m is an integer of 1 to about 200; and K is a capping group selected from the group consisting of

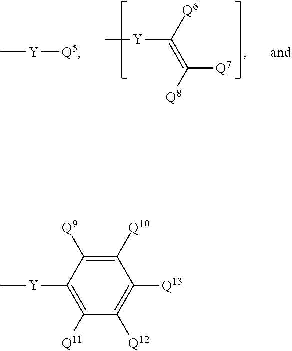

where Q⁵ is C₁-C₁₂ alkyl; Q⁶, Q⁷ and Q⁸ are each independently selected from the group consisting of hydrogen, C₁-C₁₂ alkyl, C₂-C₁₂ alkenyl, C₆-C₁₈ aryl, C₇-C₁₈ alkyl-substituted aryl, C₇-C₁₈ aryl-substituted alkyl, C₂-C₁₂ alkoxycarbonyl, C₇-C₁₈ aryloxycarbonlyl, C₈-C₁₈ alkyl-substituted aryloxycarbonyl, C₈-C₁₈ aryl-substituted alkoxycarbonyl, nitrile, formyl, carboxylate, imidate, and thiocarboxylate; and Q⁹, Q¹⁰, Q¹¹, Q¹² and Q¹³ are each independently selected from the group consisting of hydrogen, C₁-C₁₂ alkyl, hydroxy, and amino; and Y is a divalent group selected from the group consisting of

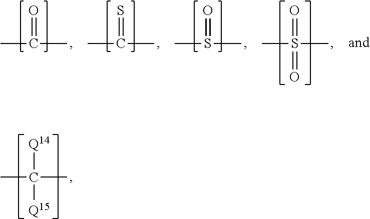

where Q¹⁴ and Q¹⁵ are each independently selected from the group consisting of hydrogen and C₁-C₁₂ alkyl.

In one embodiment, A is the residuum of a phenol, including polyfunctional phenols, and includes radicals of the structure

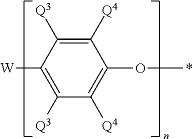

where Q³ and Q⁴ are defined as above, W is hydrogen, C₁-C₁₈ hydrocarbyl, or C₁-C₁₈ hydrocarbyl containing a substituent, for example, a carboxylic acid, aldehyde, alcohol, amino radical, sulfur, sulfonyl, sulfuryl, oxygen, C₁-C₁₂ alkylidene or other such bridging group having a valence of 2 or greater to result in various bis- or higher polyphenols; and n is an integer of 1 to 100, preferably 1 to 3.

In other embodiments, A is the residuum of a monohydric phenol, a diphenol, for example, 2,2′,6,6′-tetramethyl-4,4′-diphenol or of a bisphenol, for example, bisphenol A.

Thus, in one embodiment, the capped poly(arylene ether) is produced by capping a poly(arylene ether) consisting essentially of the polymerization product of at least one monohydric phenol having the structure

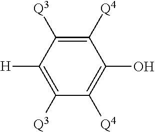

where Q³ and Q⁴ are defined as above. Suitable examples of monohydric phenols include, but are not limited to, 2,6-dimethylphenol and 2,3,6-trimethylphenol. The poly(arylene ether) may also be a copolymer of at least two monohydric phenols, such as 2,6-dimethylphenol and 2,3,6-trimethylphenol.

In yet another embodiment, the capped poly(arylene ether) includes a di-capped poly(arylene ether) having the structure

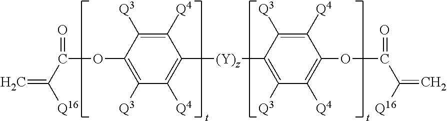

where in each occurrence, Q³ and Q⁴ are defined as above; in each occurrence Q¹⁶ is independently hydrogen or methyl; in each occurrence t is an integer of 1 to about 100; z is 0 or 1; and Y has a structure selected from

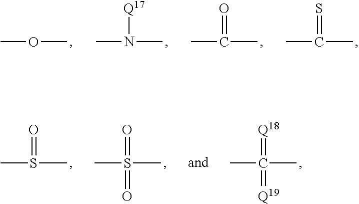

where in each occurrence of Q¹⁷ and Q¹⁸ and Q¹⁹ are independently selected from hydrogen and C₁-C₁₂ hydrocarbyl.

Procedures for capping poly(arylene ethers) are known to those skilled in the art, for example, as taught in U.S. Pat. Nos. 6,306,978 and 6,627,704, the contents of which are incorporated herein by reference. Thus, the capped poly(arylene ether) may be formed by the reaction of an uncapped poly(arylene ether) with a capping agent. Capping agents include, but are not limited to, monomers or polymers containing anhydride, acid chloride, epoxy, carbonate, ester, isocyanate, or cyanate ester radicals. For example, the capping agent may be acetic anhydride, succinic anhydride, maleic anhydride, salicylic anhydride, acrylic, methacrylic anhydride, a polyester comprising salicylate units, homopolyesters of salicylic acid, acrylic anhydride, methacrylic anhydride, glycidyl acrylate, glycidyl methacrylate, di(4-nitrophenyl)carbonate, phenylisocyanate, 3-isopropenyl-alpha, alpha-dimethylphenylisocyanate, cyanatobenzene, or 2,2-bis(4-cyanatophenyl)propane).

In still another embodiment, the functionalized poly(arylene ether) includes a ring-functionalized poly(arylene ether) having repeating structural units of the formula

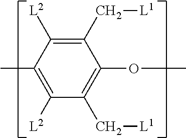

where in each occurrence L¹ and L² are independently hydrogen, a C₁-C₁₂ alkyl group, an alkenyl group represented by the formula

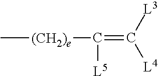

where L³, L⁴ and L⁵ are independently hydrogen or methyl and e is an integer of 0 to 4, or an alkynyl group represented by the formula

—(CH₂)_{f}—C≡C-L⁶

where L⁶ is hydrogen, methyl or ethyl and f is an integer of 0 to 4; and wherein about 0.02 mole percent to about 25 mole percent of the total L¹ and L² substituents are alkenyl and/or alkynyl groups.

In another embodiment, the ring-functionalized poly(arylene ether) is the product of a melt reaction of a poly(arylene ether) and an α,β-unsaturated carbonyl compound or a β-hydroxy carbonyl compound. Examples of α,β-unsaturated carbonyl compounds include maleic anhydride and citriconic anhydride. An example of β-hydroxy carbonyl compound includes citric acid. The functionalization may be carried out by melt mixing the poly(arylene ether) with the desired carbonyl compound at a temperature of about 190° C. to about 290° C.

According to another embodiment, the functionalized poly(arylene ether) includes at least one terminal functional group selected from carboxylic acid glycidyl ether, vinyl ether, and anhydride. Suitable methods for preparing these may be found at, for example, EP 0261574B1, U.S. Pat. Nos. 6,794,481 and 6,835,785, and U.S. Pat. Publ. Nos. 2004/0265595 and 2004/0258852, the contents of which are incorporated herein by reference.

In some embodiments, the functionalized poly(arylene ether) has a number average molecular weight of about 500 g/mol to about 18,000 g/mol.

The allyl monomer may be a mono-, di- or poly-allyl monomer or a mixture thereof. According to one embodiment, the allyl monomer is selected from triallyl isocyanurate, trimethallyl isocyanurate, triallyl cyanurate, trimethallyl cyanurate, diallyl amine, triallyl amine, diacryl chlorendate, allyl acetate, allyl benzoate, allyl dipropyl isocyanurate, allyl octyl oxalate, allyl propyl phthalate, butyl allyl malate, diallyl adipate, diallyl carbonate, diallyl dimethyl ammonium chloride, diallyl fumarate, diallyl isophthalate, diallyl malonate, diallyl oxalate, diallyl phthalate, diallyl propyl isocyanurate, diallyl sebacate, diallyl succinate, diallyl terephthalate, diallyl tatolate, dimethyl allyl phthalate, ethyl allyl malate, methyl allyl fumarate, and methyl methallyl malate. Of these monomers, triallyl isocyanurate (hereinafter referred to as TAIC) and trimethallyl isocyanurate (hereinafter referred to as TMAIC) are especially desirable.

The advancement of the poly(arylene ether) is carried out by reacting the poly(arylene ether) with the allyl monomer optionally in the presence of a catalyst. In one embodiment, the catalyst is a metal acetyl acetonate having the structure

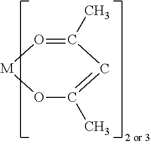

where M is selected from aluminum, barium, cadmium, calcium, cerium (III), chromium (III), cobalt (II), cobalt (III), copper (II), indium, iron (III), lanthanum, lead (II), manganese (II), manganese (III), neodymium, nickel (II), palladium (II), potassium, samarium, sodium, terbium, titanium, vanadium, yttrium, zinc and zirconium.

In other embodiments, the catalyst is an organic peroxide, such as, dicumyl peroxide, tert-butyl cumyl peroxide, bis(tert-butylperoxyisopropyl)benzene, di-tert-butyl peroxide, 2,5-dimethylhexane-2,5-dihydroperoxide, 2,5-dimethylhexyne-3,2,5-dihydroperoxide, dibenzoyl peroxide, bis-(2,4-dichlorobenzoyl)peroxide or tert-butyl perbenzoate. In still other embodiments, the catalyst is a cobalt salt, for example, cobalt octoate or cobalt naphthenate, or a metal catalyst, for example, manganese, or cyanuric acid anhydrous. In another embodiment, the catalyst is Grubbs catalyst having the formula

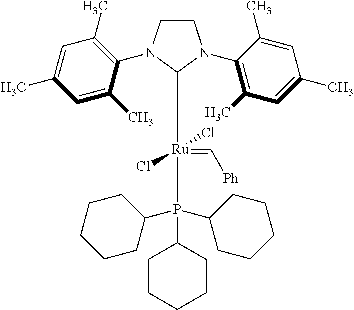

The amount of catalyst used may range from about 0.25 parts to about 1.25 parts, preferably from about 0.5 parts to about 1 part, per 100 parts by weight of the poly(arylene ether).

According to one embodiment, the advancement reaction begins by contacting the poly(arylene ether) with the allyl monomer and optionally the catalyst to form an advancement reaction mixture. The amount of poly(arylene ether) and allyl monomer contacted in the advancement reaction includes greater than 50% by weight poly(arylene ether) and less than 50% by weight allyl monomer, based on the total weight of the advancement reaction mixture. In another embodiment, the amounts of poly(arylene ether) and allyl monomer contacted in the advancement reaction includes at least about 50.5 to about 70 parts by weight poly(arylene ether) and at least about 30 to about 49.5 parts by weight allyl monomer, based on 100 parts by weight of the advancement reaction mixture. In yet another embodiment, the amounts of poly(arylene ether) and allyl monomer contacted in the advancement reaction includes from at least about 51-60 parts by weight poly(arylene ether) to at least about 40-49 parts by weight allyl monomer, based on 100 parts by weight of the advancement reaction mixture.

The conditions under which the advancement reaction occurs include full vacuum and at a temperature ranging from at least about 140° C. to less than about 150.5° C. The reaction is allowed to continue for a sufficient period of time to allow the poly(arylene ether) prepolymer to reach a desired average molecular weight. According to one embodiment, the advancement reaction is allowed to continue until the poly(arylene ether) prepolymer reaches an average molecular weight of at least 40,000 g/mol. In another embodiment, the advancement reaction is allowed to continue until the poly(arylene ether) reaches an average molecular weight of at least 50,000 g/mol, and in still other embodiments, it is allowed to continue until the poly(arylene ether) reaches an average molecular weight of at least about 60,000 g/mol. In a further embodiment, the advancement reaction is allowed to continue until the poly(arylene ether) reaches an average molecular weight of no more than about 160,000 g/mol, and in other embodiments, the reaction is allowed to continue until the poly(arylene ether) reaches an average molecular weight of no more than about 140,000 g/mol. The reaction time need to reach the desired average molecular weight will vary, but in most embodiments will typically range from about 0.1 hours to about 20 hours, preferably from about 0.5 hours to about 16 hours.

Flame Retardant

In another aspect, the thermosetting resin composition may further include a phosphonated flame retardant. In certain embodiments, the thermosetting resin composition includes between about 1 part by weight to about 20 parts by weight, per 100 parts by weight of the thermosetting resin composition, of the phosphonated flame retardant. In other embodiments, the thermosetting resin composition includes between about 4 parts by weight to about 15 parts by weight of the phosphonated flame retardant, and preferably between about 5 parts by weight to about 10 parts by weight, per 100 parts by weight of the thermosetting resin composition, of the phosphonated flame retardant.

The exact chemical form of the phosphonated flame retardant can vary based on thermosetting resin composition. For example, in certain embodiments, the phosphonated flame retardant has a formula as shown below in formulae (5)-(7):

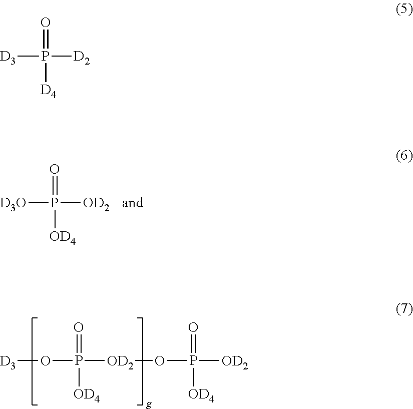

In formulae (5)-(7), D₂, D₃ and D₄ each may be independently selected from the group consisting of substituted or unsubstituted alkyl, substituted or unsubstituted aryl, substituted or unsubstituted alicyclic and substituted or unsubstituted heterocyclic groups that include nitrogen, oxygen and/or phosphorous; and g is an integer from 1 to 20.

Exemplary commercially available materials that can be used include, but are not limited to, ammonia polyphosphates such as Exolit APP-422 and APP-423 (commercially available from Clariant), and Antiblaze® MC flame retardants (commercially available from Albemarle), melamine polyphosphates such as Melapurg-200 and Melapurg-MP (commercially available from Ciba) and Fyrol(V-MP) (commercially available from Akzo Nobel), organic phosphonates such as OP-930 and OP-1230 (commercially available from Clariant) and polyphenylene phosphonates such as Fyrol PMP (commercially available from Akzo Nobel).

Optional Additives

The thermosetting resin composition may also include, if necessary, additives for enhancing strength, release properties, hydrolysis resistance, electrical conductivity and other characteristics. The additives may be added to the thermosetting resin composition in an amount of less than about 50 parts by weight, preferably less than about 30 parts by weight and most preferably less than about 20 parts by weight, per 100 parts by weight of the thermosetting resin composition.

Such optional additives may include inert, particulate fillers such as talc, clay, mica, silica, alumina, and calcium carbonate. Fabric wettability enhancers (e.g. wetting agents and coupling agents) may also be advantageous under certain conditions. In addition, such materials as antioxidants, thermal and ultraviolet stabilizers, lubricants, antistatic agents, micro or hollow spheres, dyes, and pigments may also be present.

Organic Solvent

In some embodiments, the thermosetting resin composition may be dissolved or dispersed in an organic solvent. The amount of solvent is not limited, but typically is an amount sufficient to provide a concentration of solids in the solvent of at least 30% to no more than 90% solids, preferably between about 55% and about 85% solids, and more preferably between about 60% and about 75% solids.

The organic solvent is not specifically limited and may be a ketone, an aromatic hydrocarbon, an ester, an amide, a heterocyclic acetal or an alcohol. More specifically, examples of organic solvents which may be used include, acetone, methyl ethyl ketone, methyl isobutyl ketone, cyclohexanone, toluene, xylene, methoxyethyl acetate, ethoxyethyl acetate, butoxyethyl acetate, ethyl acetate, N-methylpyrrolidone formamide, N-methylformamide, N,N-dimethylacetamide, methanol, ethanol, ethylene glycol, ethylene glycol monomethyl ether, ethylene glycol monoethyl ether, diethylene glycol, triethylene glycol monomethyl ether, triethylene glycol monoethyl ether, triethylene glycol, propylene glycol monomethyl ether, dipropylene glycol monoethyl ether, propylene glycol monopropyl ether, dipropylene glycol monopropyl ether, 1.3-dioxolane and mixtures thereof.

The thermosetting resin compositions of the present disclosure can be prepared in known manner, for example, by premixing individual components and then mixing these premixes, or by mixing all of the components together using customary devices, such as a stirred vessel, stirring rod, ball mill, sample mixer, static mixer or ribbon blender. Once formulated, the thermosetting resin composition of the present disclosure may be packaged in a variety of containers such as steel, tin, aluminium, plastic, glass or cardboard containers.

According to another embodiment, the thermosetting resin composition of the present disclosure is prepared by mixing together from about 3-20 parts by weight of the polymaleimide prepolymer and from about 80-97 parts by weight of the poly(arylene ether) prepolymer. In another embodiment, the thermosetting resin composition is prepared by mixing together from about 3-20 parts by weight of the polymaleimide prepolymer, from about 80-97 parts by weight of the poly(arylene ether), and then solvent, at an amount sufficient to provide a concentration of solids in the solvent of at least 30% to no more than 90% solids. The thermosetting resin composition, once prepared, may then be applied to an article or substrate and cured at a temperature greater than 150° C. to form a composite article.

The thermosetting resin composition of the present disclosure can be used to make composite articles by techniques well known in the industry such as by pultrusion, moulding, encapsulation or coating. The thermosetting resin compositions of the present disclosure, due to their thermal properties, are especially useful in the preparation of articles for use in high temperature continuous use applications. Examples include electrical laminates and electrical encapsulation. Other examples include molding powders, coatings, structural composite parts, such as radome composites for aerospace applications, and gaskets.

In another aspect, the present disclosure provides a process for preparing a resin coated article. The process steps include contacting an article or a substrate with a thermosetting resin composition of the present disclosure. Compositions of the present disclosure may be contacted with the article or substrate by any method known to those skilled in the art. Examples of such contacting methods include powder coating, spray coating, die coating, roll coating, resin infusion process, and contacting the article with a bath containing the thermosetting resin composition. In one embodiment the article or substrate is contacted with the thermosetting resin composition in a varnish bath. In another embodiment, the present disclosure provides for articles or substrates, especially prepregs and laminates, prepared by the process of the present disclosure.

In yet another aspect, the present disclosure provides a prepreg obtained by impregnating reinforcement with the thermosetting resin composition of the present disclosure.

The present disclosure also provides a metal-coated foil obtained by coating a metal foil with the thermosetting resin composition of the present disclosure.

In still another aspect, the present disclosure also provides a laminate with enhanced properties obtained by laminating the above prepreg and/or the above metal-coated foil.

The thermosetting resin composition of the present disclosure is amenable to impregnation of reinforcements, for example, glass cloth or quartz cloth, and cures into products having heat resistance and/or low dielectric loss at high frequency, so that the composition is suitable for the manufacture of laminates which have a well-balance of properties, are well-reliable with respect to mechanical strength and electrically insulated at high temperatures. The reinforcements or reinforcing materials which may be coated with the thermosetting resin composition of the present disclosure include any material which would be used by one skilled in the art in the formation of composites, prepregs, and laminates. Examples of appropriate substrates include fiber-containing materials such as woven cloth, mesh, mat, fibers, and unwoven aramid reinforcements. Preferably, such materials are made from glass, fiberglass, quartz, paper, which may be cellulosic or synthetic, a thermoplastic resin substrate such as aramid reinforcements, polyethylene, poly(p-phenyleneterephthalamide), polyester, polytetrafluoroethylene and poly(p-phenylenebenzobisthiazole), syndiotatic polystyrene, carbon, graphite, ceramic or metal. Preferred materials include glass or fibreglass or quartz, in woven cloth or mat form.

In one embodiment, the reinforcing material is contacted with a varnish bath comprising the thermosetting resin composition of the present disclosure dissolved and intimately admixed in a solvent or a mixture of solvents. The coating occurs under conditions such that the reinforcing material is coated with the thermosetting resin composition. Thereafter the coated reinforcing materials are passed through a heated zone at a temperature sufficient to cause the solvents to evaporate, but below the temperature at which the thermosetting resin composition undergoes significant cure during the residence time in the heated zone.

The reinforcing material preferably has a residence time in the bath of from 1 second to 300 seconds, more preferably from 1 second to 120 seconds, and most preferably from 1 second to 30 seconds. The temperature of such bath is preferably from 0° C. to 100° C., more preferably from 10° C. to 40° C., and most preferably from 15° C. to 30° C. The residence time of the coated reinforcing material in the heated zone is from 0.1 minute to 15 minutes, more preferably from 0.5 minutes to 10 minutes, and most preferably from 1 minute to 5 minutes.

The temperature of such zone is sufficient to cause any solvents remaining to volatilize away yet not so high as to result in a complete curing of the components during the residence time. Preferable temperatures in such zone are from 80° C. to 250° C., more preferably from 100° C. to 225° C., and most preferably from 150° C. to 210° C. Preferably there is a means in the heated zone to remove the solvent, either by passing an inert gas through the oven, or drawing a slight vacuum on the oven. In many embodiments the coated materials are exposed to zones of increasing temperature. The first zones are designed to cause the solvent to volatilize so it can be removed. The later zones are designed to result in partial cure of the thermosetting resin components (B-staging).

One or more sheets of prepreg are preferably processed into laminates optionally with one or more sheets of electrically-conductive material such as copper. In such further processing, one or more segments or parts of the coated reinforcing material are brought in contact with one another and/or the conductive material. Thereafter, the contacted parts are exposed to elevated pressures and temperatures sufficient to cause the components to cure wherein the resin on adjacent parts react to form a continuous resin matrix between the reinforcing material. Before being cured the parts may be cut and stacked or folded and stacked into a part of desired shape and thickness. The pressures used can be anywhere from 1 psi to 1000 psi with from 10 psi to 800 psi being preferred. The temperature used to cure the resin in the parts or laminates, depends upon the particular residence time, pressure used, and resin used. Preferred temperatures which may be used are between 100° C. and 250° C., more preferably between 120° C. and 220° C., and most preferably between 170° C. and 200° C. The residence times are preferably from 10 minutes to 120 minutes and more preferably from 20 minutes to 90 minutes.

In one embodiment, the process is a continuous process where the reinforcing material is taken from the oven and appropriately arranged into the desired shape and thickness and pressed at very high temperatures for short times. In particular such high temperatures are from 180° C. to 250° C., more preferably 190° C. to 210° C., at times of 1 minute to 10 minutes and from 2 minutes to 5 minutes. Such high speed pressing allows for the more efficient utilization of processing equipment. In such embodiments the preferred reinforcing material is a glass web or woven cloth.

In some embodiments it is desirable to subject the laminate or final product to a post cure outside of the press. This step is designed to complete the curing reaction. The post cure is usually performed at from 130° C. to 220° C. for a time period of from 20 minutes to 200 minutes. This post cure step may be performed in a vacuum to remove any components which may volatilize.

In another aspect, the thermosetting resin composition, upon mixing and curing, provides a cured product, for example a laminate, with excellent well-balanced properties. The properties of the cured product that are well-balanced in accordance with the present disclosure include at least two of: a glass transition temperature (Tg) of greater than about 170° C., preferably greater than about 175° C., and more preferably greater than about 180° C.; a flame retardancy in terms of a UL94 ranking of at least V1 and preferably V0; a dielectric loss tangent of less than about 0.0034 at 5 GHz, preferably less than about 0.005 at 16 GHz; and a dielectric constant of less than about 3.00 at 5 GHz, preferably less than about 2.80 at 5 GHz, more preferably less than about 3.00 at 16 GHz, and even more preferably less than about 2.70 at 16 GHz. In one aspect, the thermosetting resin composition is cured at a cure cycle that includes heating the composition at a temperature of about 120° C. for about 16 hours, then further heating at a temperature of about 170° C. for about 1 hour, then further heating at a temperature of about 200° C. for about 1 hour, then further hearing at a temperature of about 230° C. for about 1 hour and finally heating at a temperature of about 250° C. for about 1 hour.

Although making and using various embodiments of the present disclosure have been described in detail above, it should be appreciated that the present disclosure provides many applicable inventive concepts that can be embodied in a wide variety of specific contexts. The specific embodiments discussed herein are merely illustrative of specific ways to make and use the disclosure, and do not delimit the scope of the disclosure.

What is claimed is:

1. A thermosetting resin composition comprising:
(a) a polymaleimide prepolymer resulting from the advancement reaction of a polyimide and an alkenylphenol, alkenylphenol ether or mixture thereof in the presence of an amine catalyst; and
(b) a poly(arylene ether) prepolymer resulting from the advancement reaction of a poly(arylene ether) and an allyl monomer optionally in the presence of a catalyst; characterized in that a resultant cured product formed by curing the thermosetting resin composition contains at least two of the following well-balanced properties: (1) a glass transition temperature (Tg) of greater than about 170° C.; (2) a UL94 flame retardancy ranking of at least V1; (3) a dielectric loss tangent of less than about 0.005 at 16 GHz; and, (4) a dielectric loss constant of less than about 3.00 at 16 GHz.

2. The thermosetting resin composition of claim 1, wherein the polyimide is a bismaleimide of the formula 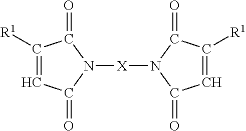
where R¹ is hydrogen or methyl and X is —CᵢH₂ᵢ— with i=2 to 20, —CH₂CH₂SCH₂CH₂—, phenylene, naphthalene, xylene, cyclopentylene, 1,5,5-trimethyl-1,3-cyclohexylene, 1,4-cyclohexylene, 1,4-bis-(methylene)-cyclohexylene, or groups of the formula 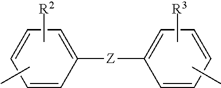
where R² and R³ independently are methyl, ethyl, or hydrogen and Z is a direct bond, methylene, 2,2-propylidene, —CO—, —O—, —S—, —SO— or —SO₂—.

3. The thermosetting resin composition of claim 2, wherein the poly(arylene ether) comprises one or more compounds containing a plurality of structural units having the formula 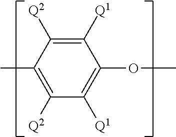
where for each structural unit, each occurrence of Q¹ is independently primary or secondary C₁-C₁₂ hydrocarbyl, C₁-C₁₂ hydrocarbylthio or C₁-C₁₂ hydrocarbyloxy; and each occurrence of Q² is independently primary or secondary C₁-C₁₂ hydrocarbyl, C₁-C₁₂ hydrocarbyloxy or C₁-C₁₂ hydrocarbyloxy.

4. The thermosetting resin composition of claim 2, wherein the poly(arylene ether) is a functionalized poly(arylene ether) selected from a capped poly(arylene ether), a di-capped poly(arylene ether), a ring-functionalized poly(arylene ether) and a poly(arylene ether) resin containing at least one terminal functional group selected from carboxylic acid, glycidyl ether, vinyl ether and anhydride.

5. The thermosetting resin composition of claim 1, wherein a catalyst is present during the advancement reaction of the poly(arylene ether) and the allyl monomer.

6. The thermosetting resin composition of claim 5, wherein the catalyst is a metal acetyl acetonate having the structure 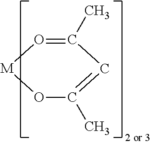
where M is selected from aluminum, barium, cadmium, calcium, cerium (III), chromium (III), cobalt (II), cobalt (III), copper (II), indium, iron (III), lanthanum, lead (II), manganese (II), manganese (III), neodymium, nickel (II), palladium (II), potassium, samarium, sodium, terbium, titanium, vanadium, yttrium, zinc and zirconium.

7. The thermosetting resin composition of claim 1, wherein the catalyst is Grubbs catalyst.

8. The thermosetting resin composition of claim 1, further comprising a phosphonated flame retardant.

9. The thermosetting resin composition of claim 1, further comprising an organic solvent.

10. A thermosetting resin composition comprising:
(a) 3-20 parts by weight, per 100 parts by weight of the thermosetting resin composition, of a polymaleimide prepolymer resulting from the advancement reaction of a polyimide and an alkenylphenol, alkenylphenol ether or mixture thereof in the presence of an amine catalyst; and
(b) 80-97 parts by weight, per 100 parts by weight of the thermosetting resin composition, of a poly(arylene ether) prepolymer resulting from the advancement reaction of a poly(arylene ether) and an allyl monomer optionally in the presence of a catalyst; characterized in that a resultant cured product formed by curing the thermosetting resin composition contains at least two of the following well-balanced properties: (1) a glass transition temperature (Tg) of greater than about 170° C.; (2) a UL94 flame retardancy ranking of at least V1; (3) a dielectric loss tangent of less than about 0.005 at 16 GHz; and, (4) a dielectric loss constant of less than about 3.00 at 16 GHz.

11. The thermosetting resin composition of claim 9, wherein the amounts of poly(arylene ether) and allyl monomer contacted in the advancement reaction includes from at least about 51-60 parts by weight of the poly(arylene ether) and at least about 40-49 parts by weight of the allyl monomer, based on 100 parts by weight of the advancement reaction mixture.

12. A method for producing a thermosetting resin composition comprising mixing together:
(a) 3-20 parts by weight, per 100 parts by weight of the thermosetting resin composition, of a polymaleimide prepolymer resulting from the advancement reaction of a polyimide and an alkenylphenol, alkenylphenol ether or mixture thereof in the presence of an amine catalyst; and
(b) 80-97 parts by weight, per 100 parts by weight of the thermosetting resin composition, of a poly(arylene ether) prepolymer resulting from the advancement reaction of a poly(arylene ether) and an allyl monomer optionally in the presence of a catalyst; and optionally
(c) a phosphonated flame retardant; and
(e) an organic solvent.

13. A thermosetting resin composition produced according to the method of claim 11.

14. A process for producing a coated article, comprising coating the article with a thermosetting resin composition according to claim 1, and heating the article to cure the thermosetting resin composition.

15. A prepreg comprising: (a) a woven fabric, and (b) a thermosetting resin composition according to claim 1.

16. A prepreg according to claim 15, wherein the woven fabric comprises fibreglass or quartz.

17. A laminate comprising: (a) a substrate including a thermosetting resin composition according to claim 1; and (b) a layer of metal disposed on at least one surface of said substrate.

18. The laminate of claim 15 wherein the substrate further comprises a reinforcement of a woven glass or quarts fabric, wherein the thermosetting resin composition is impregnated on the woven glass or quartz fabric.

19. A printed circuit board (PCB) made of the laminate of claim 15.

20. A radome composite made of the laminate of claim 15.
